(19) United States
(12) Patent Application Publication
(10) Pub. No.: US 2024/0275710 A1
(43) Pub. Date: Aug. 15, 2024

(54) NETWORK VALIDATION USING A MULTI-TIERED APPLICATION TRAFFIC SIMULATOR

(71) Applicant: Arista Networks, Inc., Santa Clara, CA (US)

(72) Inventors: Gary Charles Nigg, Harvard, MA (US); Shashank Hegde, Sunnyvale, CA (US); Sandip Shah, Fremont, CA (US)

(21) Appl. No.: 18/168,015

(22) Filed: Feb. 13, 2023

(51) Int. Cl. H04L 43/55; G06F 30/20

(52) U.S. Cl. CPC H04L 43/55; G06F 30/20

(57) ABSTRACT

A traffic generation tool is provided for simulating a multi-tiered application for network validation. A multi-tiered application can include at least one frontend service and multiple backend services. The traffic generation tool can load configuration files that specify the behavior of each endpoint within the frontend and backend services of the multi-tiered application. The traffic generation tool can direct a client to send a request to the frontend service. The traffic generation tool can, in response to receiving the request at the frontend service, sequence a chain of additional requests using one or more different network communications protocols to the backend services.

### BACKGROUND

A multi-tiered application can include many software components running on disparate servers all connected via one or more computer networks. For instance, a multi-tiered application can include a user-facing application such as a web server. In practice, the web server can receive a user request, which in turn can cause the web server to generate additional traffic flows involving a variety of different networking protocols with many other servers.

It can be challenging to design, develop, and deploy multi-tiered applications in a real computer network. Conventional traffic generation tools treat each individual traffic flow as a separate entity and thus do not provide the user with an efficient way of linking together the various traffic flows. This limitation makes it difficult to validate a computer network's design prior to the actual deployment of a multi-tiered application. It is within this context that the embodiments herein arise.

### BRIEF DESCRIPTION OF THE DRAWINGS

FIG. 1 is a diagram of an illustrative multi-tiered application in accordance with some embodiments.

FIG. 2 is a sequencing diagram showing an illustrative sequence of requests and responses that can be simulated using a traffic generation tool in accordance with some embodiments.

FIG. 3 is a diagram of an illustrative configuration file for a client endpoint in accordance with some embodiments.

FIG. 4 is a diagram of an illustrative configuration file for an application endpoint in accordance with some embodiments.

FIG. 5 is a diagram of an illustrative configuration file for a backend endpoint in accordance with some embodiments.

FIG. 6 is a flow chart of illustrative steps for operating a traffic generation tool to emulate traffic flows involving various network communication protocols in accordance with some embodiments.

FIG. 7 is a diagram showing an illustrative traffic generation tool implemented on computing equipment in accordance with some embodiments.

### DETAILED DESCRIPTION

A traffic generation tool is provided for validating a network by emulating the traffic behavior of one or more multi-tiered applications. A multi-tiered application may include one or more frontend services configured to receive requests from one or more clients. These client requests cause the multi-tiered application to trigger additional requests to one or more backend services. An example of a frontend service can be a web server, whereas backend service examples can include a database service, a data storage service, an analytics service, an authentication service, a content distribution network service, or other application-specific service(s) implemented on one or more backend servers.

The traffic generation tool can load one or more configuration files that specify the behavior of each service request of a multi-tiered application. When the frontend service receives a client request, the traffic generation tool can automatically spawn off any combination of serial and/or concurrent backend requests which can be dependent upon one another. Serial backend requests can refer to requests where the response from one backend request initiates a request to another backend service. Concurrent backend requests occur when multiple backend requests are issued in parallel. The configuration files can also define the networking protocols used by each of the frontend and backend services. The traffic generation tool can therefore be used to mimic the daisy chaining (linking) of dependent service requests involving varying types of protocol traffic. A traffic generation tool configured and operated in this way can help dramatically speed up the development and deployment of real-world multi-tiered applications in a computer network.

The present embodiments relate to an application framework that partitions tasks or workloads between service requesters (commonly referred to as “clients”) and providers of a resource or service (commonly referred to as “servers”). Such distributed application can be referred to as a client-server architecture, where clients and servers are implemented on the same system or as separate hardware components communicating over a computer network. Clients and servers can communicate via a request-response messaging scheme where a client sends a request to another program to access services provided by a server. The server can then provide a corresponding response back to the client. A server can run multiple programs with shared resources and can distribute work among several clients.

Clients and servers can communicate using a plurality of different network communications protocols. As an example, traffic between a client and a server can be managed using Transmission Control Protocol (TCP). As other examples, traffic between clients and servers can be managed using User Datagram Protocol (UDP), Stream Control Transmission Protocol (SCTP) or other transport layer protocols, Internet Control Message Protocol (ICMP), Hypertext Transfer Protocol (HTTP), File Transfer Protocol (FTP), Border Gateway Protocol (BGP), or other application layer protocols.

Client and servers can be interconnected using network devices including one or more routers, one or more switches, one or more bridges, one or more hubs, one or more repeaters, one or more firewalls, one or more devices serving other networking functions, device(s) that include a combination of these functions, or other types of networking elements. Network devices may include processing circuitry based on one or more microprocessors, graphics processing units (GPUs), host processors, general-purpose processors, microcontrollers, digital signal processors, application specific integrated circuits (ASICs), application specific system processors (ASSPs), programmable logic devices such as field-programmable gate arrays (FPGAs), a combination of these processors, or other types of processors.

Various types of client-server architectures or models have been developed. In a single-tier architecture, a diversity of services such as a user-presentation layer, an application (business) layer, and a database management layer can all be integrated into a software package on a single electronic device. In a two-tier architecture, a client can include business logic that communicates directly with a server that includes database logic. In two-tier architectures, the client and server interact with each other without any intermediary components. The present embodiments may generally relate to client-server architectures with two or more tiers sometimes referred to and defined as “multi-tiered” applications.

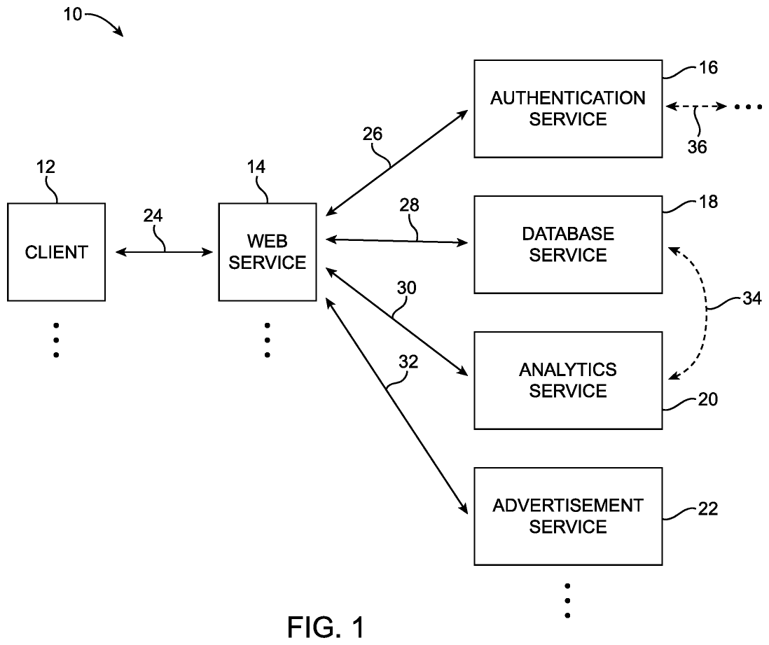

FIG. 1 is a diagram of an illustrative multi-tiered application such as multi-tiered application 10. An application can include a group of services that are deployed on the cloud, in a datacenter, or distributed across multiple datacenters or data systems. Each service in multi-tiered application 10 can include one or more endpoints or other computing resources configured to handle bare metal workloads, VMware based workloads, container workloads, or cloud based workloads. As shown in FIG. 1, multi-tiered application 10 can include one or more frontend services such as web service 14, and one or more backend services such as authentication service 16, database service 18, analytics service 20, and advertisement service 22 (just to name a few). Frontend service 14 can receive requests from one or more clients 12. “Frontend” services generally refer to services that are client or user facing, whereas “backend” services generally refer to services that are used to access application/business data, administer one or more databases, perform authentication, authorization or other security related operations, perform data backup and data transformation operations, and/or perform other server related functions.

Client(s) 12 are sometimes referred to as users or client services and can be referred to as being part of a client tier, user interface tier, or presentation tier. A service that only sends requests to other servers but does not itself receive requests from other clients is sometimes referred to and defined herein as a “client-only” service or resources. Application 10 can include one or more clients, two or more clients, three or more clients, two to five clients, five to ten clients, or more than ten clients that send user requests to one or more frontend services. Client 12 may, for example, communicate with web service 14 via path 24 (e.g., via an Internet connection).

Web service 14 may be implemented on one or more web servers. Web service 14 can be referred to as being part of an application tier that serves as middleware between the client tier and the various backend services. In general, any service that can not only receive requests from one or more clients but can also itself send requests to other servers or backend services can be said to have client and server functionality.

The backend services such as authentication service 16, database service 18, analytics service 20, and advertisement service 22 are sometimes referred to as being part of a data tier. In general, any service that can only receive requests from another server but cannot itself send requests to other servers or backend services can be referred to and defined herein as a “server-only” (or data-only) service or resources. Thus, application 10 having an application tier that receives requests from a client tier and having a data tier that receives requests from the application tier can be referred to as being a multi-tiered application with two or more tiers. In general, an N-tiered application can include N tiers, where N is three or more, two or more, four or more, five or more, five to ten, or any integer greater than 10. Compared to single-tier architectures, the multi-tiered architecture of application 10 can help provide improved data control, data security, and data integrity.

In the example of FIG. 1, web service 14 can send requests to and receive corresponding responses from authentication service 16 via communications link 26 using a first networking protocol. Additionally or alternatively, web service 14 can send requests to and receive corresponding responses from database service 18 via communications link 28 using a second networking protocol that is the same or different than the first networking protocol. Additionally or alternatively, web service 14 can send requests to and receive corresponding responses from analytics service 20 via communications link 30 using a third networking protocol that is the same or different than the first and/or second networking protocols. Additionally or alternatively, web service 14 can send requests to and receive corresponding responses from advertisement service 22 via communications link 32 using a fourth networking protocol that is the same or different than the first, second, and/or third networking protocols.

Each of these backend services can be implemented on one or more servers. For example, database service 18 can be implemented on one or more database servers. As another example, analytics service 20 can be implemented on one or more analytics servers. In general, application 10 may include other frontend or backend services. In other embodiments, application 10 can also include backend services such as a data storage service, an object storage service, a file transfer service, a content distribution networking (CDN) service, a domain name system (DNS) service, a tax information reporting service, a payroll information reporting service, a video origin service, or other application specific logic.

If desired, some of the backend services can also send requests to other backend services. In the example of FIG. 1, authentication service 16 can be a server-only service or can optionally also include client functionality by also sending requests to one or more backend services (see additional backend traffic 36). If desired, some of the backend services in the same or different tier may be capable of communicating with each other. In the example of FIG. 1, database service 18 might be able to communicate with analytics service 20 via communications link 34.

Consider an example in which system 10 is being used to run an eCommerce application having a web service 14, a database service 18, and an analytics service 20. Clients 12 may first open a TCP connection to web service 14. Web service 14 may be configured to listen for requests from the clients on a designated port X. The database service 18 may be configured to listen for requests from web service 14 on a designated port Y. The analytics service 20 may be configured to listen for requests from web service 14 on a designated port Z. When web service 14 receives a request from a client, web service 14 can establish a connection and send a request to database service 18. When web service 14 receives a corresponding response from database service 18, web service 14 can subsequently establish a connection and send a request to analytics service 20. If desired, database service 18 and analytics service 20 can asynchronously communicate with each other (see link 34). When web service 14 receives a corresponding response from analytics service 20, web service 14 can then send a response back to the client. This example in which connection to database service 18 and analytics service 20 are established in a serial fashion is merely illustrative. In other scenarios, web service 14 can alternatively establish concurrent connections with database service 18 and analytics service 20 in a parallel fashion.

As shown in the example above, a multi-tiered application can involve a sequence of requests and responses between various frontend and backend services. Designing, developing, and deploying multi-tiered applications with many services can be challenging. Conventional traffic generating tools treat each individual traffic flow as a separate entity and thus do not provide the designer with an efficient way of linking together the various traffic flows needed to emulate a multi-tiered application. This limitation renders the actual development and deployment of multi-tiered applications in the real word extremely time consuming and cumbersome. This problem is made even more challenging when the various services communicate with one another using different networking protocols.

In accordance with an embodiment, a traffic generation tool is provided that is configured to simulate (emulate) a sequence of requests and responses for facilitating the design, development, and deployment of multi-tiered applications. The traffic generation tool can mimic the behavior of a multi-tiered application by providing a mechanism of linking or sequencing tier-to-tier traffic involving various different network communications protocols (e.g., the traffic generation tool can automatically daisy chain together tier-to-tier traffic of any arbitrary set of protocols). Such type of traffic generation tool provided herein can therefore sometimes be referred to as a protocol-linking traffic generation tool.

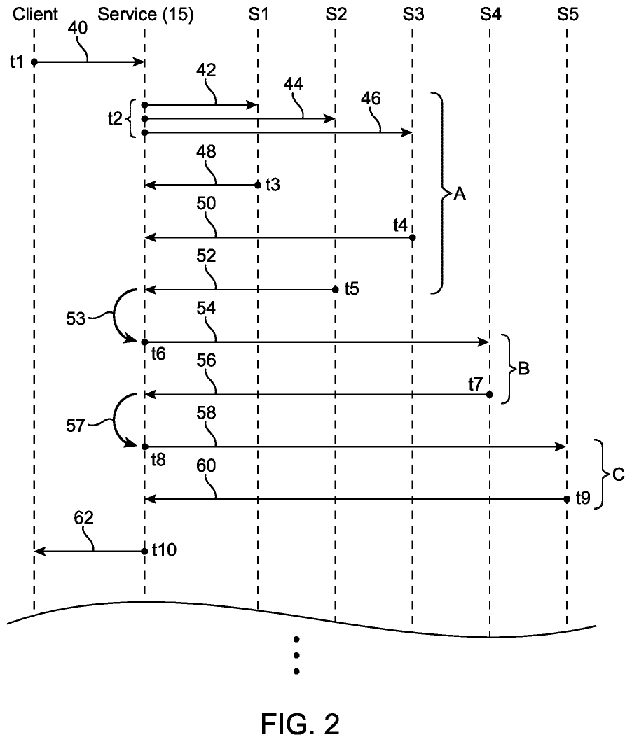

FIG. 2 is a sequencing diagram showing an illustrative sequence of requests and responses that can be emulated using a traffic generation tool in accordance with some embodiments. As shown in FIG. 2, a client can send an initial request to a service such as service 15 at time t1 (see arrow 40). Service 15 can represent a service that exhibits both server and client functionality. Service 15 can be a web service (as an example).

The initial client request 40 may cause service 15 to subsequently issue a first set of concurrent requests at time t2. In the example of FIG. 2, service 15 can issue a first request to a first backend service S1 (see arrow 42), a second request to a second backend service S2 (see arrow 44), and a third request to a third backend service S3 (see arrow 46). Second backend service S2 may be different and separate from first backend service S1. Third backend service S3 may be different and separate from first and second backend services S1 and S2. Traffic between service 15 and backend service S1 can be communicated using a first network communications protocol. Service S1 can optionally send requests to another backend service. Traffic between service 15 and backend service S2 can be communicated using a second network communications protocol that is identical or different than the first network protocol. Service S2 can optionally send requests to another backend service. Traffic between service 15 and backend service S3 can be communicated using a third network communications protocol that is identical or different than the first and second network protocols. Service S3 can optionally send requests to another backend service.

Backend requests 42, 44, and 46 may all be transmitted respectively to backend services S1, S2, and S3 at the same time (e.g., backend requests 42, 44, and 46 may be transmitted in parallel at time t2). This example in which service 15 transmits three concurrent (simultaneous) backend requests at time t2 is merely illustrative. In other embodiments, the protocol-linked traffic generation tool can simulate at least two simultaneous backend requests, three or more simultaneous backend requests, four or more simultaneous backend requests, five or more simultaneous backend requests, five to ten simultaneous backend requests, or more than ten simultaneous backend requests to respective backend services using one or more different network protocols at any given time.

At time t3, backend service S1 may send a response back to service 15 (see arrow 48). At time t4, backend service S3 may send a response back to service 15 (see arrow 50). At time t5, backend service S2 may send a response back to service 15 (see arrow 52). This example in which backend services S1, S3, and S2 send responses back to service 15 in that particular order is illustrative. In general, backend services S1, S2, and S3 can respond to service 15 in any order. The set of requests and responses starting from time t2 until time t5 is labeled as request-response group A in the example of FIG. 2.

Once service 15 receives the last response in group A, the traffic generation tool may trigger another set of request-response group such as group B (see arrow 53 for linking group A to group B). At time t6, service 15 can issue a request to a fourth backend service S4 (see arrow 54). Fourth backend service S4 may be different and separate from first, second, and third backend services S1, S2, and S3. Traffic between service 15 and backend service S4 can be communicated using a fourth network communications protocol that is identical or different than the first, second, and third network protocols. Service S4 can optionally send requests to another backend service. At time t7, backend service S4 may send a response back to service 15 (see arrow 56). The set of requests and responses starting from time t6 to time t7 is labeled as request-response group B. Here, the communications of group B are automatically triggered serially after the communications of group A (e.g., the communications of group B are said to be dependent on the communications of group A).

Once service 15 receives response 56 in group B, the traffic generation tool may trigger another set of request-response group such as group C (see arrow 57 for linking group B to group C). At time t8, service 15 can issue a request to a fifth backend service S5 (see arrow 58). Fifth backend service S5 may be different and separate from first, second, third, and fourth backend services S1, S2, S3, and S4. Traffic between service 15 and backend service S5 can be communicated using a fifth network communications protocol that is identical or different than the first, second, third, and fourth network protocols. Service S5 can optionally send requests to another backend service. At time t9, backend service S5 may send a response back to service 15 (see arrow 60). The set of requests and responses starting from time t8 to time t9 is labeled as request-response group C. Here, the communications of group C can be automatically triggered serially after the communications of group B (e.g., the communications of group C are said to be dependent on the communications of group B).

Once service 15 receives response 60 in group C, service 15 may finally respond back to the client, at time t10 (see arrow 62), to complete the initial client request at time t1. The example of FIG. 2 in which the protocol-linking traffic generation tool is configured to automatically link or daisy chain traffic associated with three different dependent request-response groups A, B, and C in series (i.e., one after another) is merely illustrative. In general, the traffic generation tool can be configured to daisy chain traffic associated with two or more request-response groups each having only one backend request or multiple concurrent backend requests, more than three request-response groups each having only one backend request or multiple concurrent backend requests, four or more request-response groups each having only one backend request or multiple concurrent backend requests, five or more request-response groups each having only one backend request or multiple concurrent backend requests, five to ten request-response groups each having only one backend request or multiple concurrent backend requests, or more than ten dependent request-response groups each having only one backend request or multiple concurrent backend requests.

Using a traffic generation tool to mimic the immediate daisy chaining (linking) of dependent service requests involving varying types of protocol traffic in this way can help dramatically speed up the development and deployment of real-world multi-tiered applications in a computer network. The traffic generation tool provided herein can be used to efficiently simulate traffic associated with hundreds or thousands of multi-tiered applications without requiring the user to separately instantiate each entity in the various multi-tiered applications currently being tested.

The traffic generation tool can load one or more configuration files that specify the behavior of each service request of a multi-tiered application. Each type of service can have a different configuration file for specifying its traffic pattern. For instance, a client-only service can include one or more client endpoints exhibiting client-only functionality (e.g., client endpoints can only send requests to and receive corresponding responses from other services but do not receive requests from other clients). A server-only service can include one or more backend endpoints exhibiting server-only functionality (e.g., backend endpoints can only receive requests from and send corresponding responses back to a client but cannot send requests to other backend services). In contrast, a service having both client and server functionality can include one or more application endpoints that can not only receive requests from a client but can also send additional requests to other backend services.

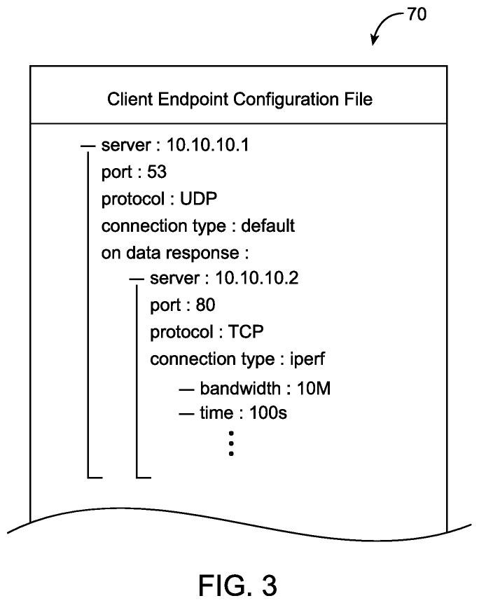

FIG. 3 is a diagram of an illustrative configuration file 70 for a client endpoint in accordance with some embodiments. As shown in FIG. 3, client endpoint configuration file 70 may specify at least one target server towards which the client endpoint can send requests. For instance, the client endpoint can be configured (based on configuration file 70) to send requests to a first (remote) server at IP address 10.10.10.1. The first server at IP address 10.10.10.1 can be configured to listen for requests from the client endpoint on a designated port 53. Configuration file 70 may further specify the network protocol and the connection type used between the client endpoint and the first server. In the example of FIG. 3, the client endpoint and the first server may communicate using UDP with a default connection type (e.g., using regular server communication schemes).

Client endpoint configuration 70 may also have an “on data response” field, which specifies how the client endpoint will behave when receiving a response from the first server. Here, when receiving a response from the first server, the client endpoint will subsequently send another request to a second (remote) server at IP address 10.10.10.2. The second server at IP address 10.10.10.2 can be configured to listen for requests from the client endpoint on a designated port 80. Configuration file 70 may further specify the network protocol and the connection type used between the client endpoint and the second server. In the example of FIG. 3, the client endpoint and the second server may communicate using TCP with an “iperf” connection type (e.g., using a performance connection type different than the default server connection type). The iperf connection type is an open source Linux tool configured to generate high volume traffic with the capability of specifying bandwidth, latency, jitter, delay, time, and/or other tier-to-tier communications parameters. This is merely illustrative. If desired, other connection types for generating client-server traffic can be employed.

The example of FIG. 3 in which the client endpoint is configured to generate two requests in series (e.g., to a first server at 10.10.10.1 and then to a second server at 10.10.10.2 is merely illustrative). In other embodiments, configuration file 70 can direct the client endpoint to send three or more requests to different servers in sequence, four or more requests to different servers in sequence, five to ten requests to different servers in sequence, or more than ten requests to different servers in sequence. If desired, configuration file 70 can also direct the client endpoint to send concurrent (simultaneous) requests to multiple servers in parallel, where the traffic to the parallel servers can employ the same or different network protocols and connection types.

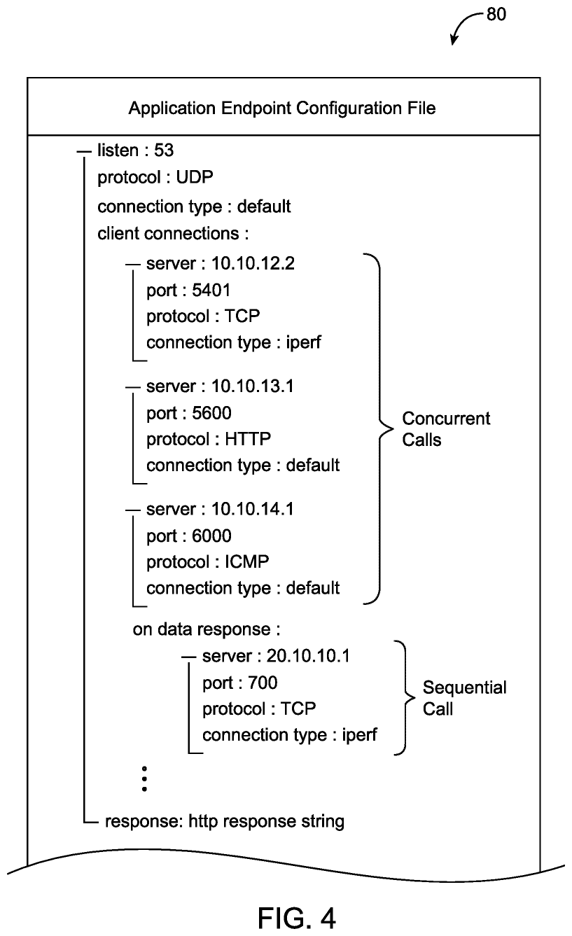

FIG. 4 is a diagram of an illustrative configuration file 80 for an application endpoint in accordance with some embodiments. The application endpoint can receive requests from one or more clients and can send requests to one or more backend services. As shown in FIG. 4, application endpoint configuration file 80 may direct the application endpoint to listen for client requests on designated port 53 via a link established using UDP with the default connection type. Configuration file 80 may further specify that, in response to receiving a client request, the application endpoint issue three concurrent requests (calls) to a third server at IP address 10.10.12.1, to a fourth server at IP address 10.10.13.1, and to a fifth server at IP address 10.10.14.1. The third server at IP address 10.10.12.1 can be configured to listen for calls from the application endpoint on a designated port 5401 and establish a connection with the application endpoint using TCP with the iperf connection type. The fourth server at IP address 10.10.13.1 can be configured to listen for calls from the application endpoint on a designated port 5600 and establish a connection with the application endpoint using HTTP with the default connection type. The fifth server at IP address 10.10.14.1 can be configured to listen for calls from the application endpoint on a designated port 6000 and establish a connection with the application endpoint using ICMP with the default connection type.

This example in which configuration file 80 directs an application endpoint to make three concurrent (parallel) backend service calls is merely illustrative. In other embodiments, an application endpoint may be configured to make two or more concurrent backend requests, three or more concurrent backend requests, four or more concurrent backend requests, five or more concurrent backend requests, five to ten concurrent backend requests, or more than ten concurrent backend requests, where the traffic to the parallel services can employ the same or different network protocols and connection types.

Application endpoint configuration 80 may also have an “on data response” field, which specifies how the application endpoint will behave after receiving responses from the third, fourth and fifth remote servers. Here, after receiving responses from all three servers (which can be received in any order), the application endpoint will subsequently send another request to a sixth (remote) server at IP address 20.10.10.1. In another arrangement, this connection to the sixth server can be linked after the applicant endpoint receives responses from any two of the three servers at IP addresses 10.10.12.1, 10.10.13.1, and 10.10.14.1. In yet another arrangement, this connection to the sixth server can be established after the applicant endpoint receives a response from any one of the three servers.

The sixth server at IP address 20.10.10.1 can be configured to listen for requests from the applicant endpoint on a designated port 700. Configuration file 80 may further specify the network protocol and the connection type used between the application endpoint and the sixth server. In the example of FIG. 4, the application endpoint and the sixth server may communicate using TCP with the iperf connection type. If desired, the application endpoint can be configured to send additional backend requests. After receiving a response from the sixth server, the applicant endpoint can send an http response string (as an example) back to the requesting client.

The example of FIG. 4 in which the application endpoint is configured to generate two groups of requests in series (e.g., where the first group of requests includes three concurrent backend requests and where the second group includes only one backend request) is merely illustrative. In other embodiments, configuration file 80 can direct the application endpoint to send three or more groups of requests in sequence, four or more groups of requests in sequence, five to ten groups of requests in sequence, or more than ten groups of requests in sequence, where each group of request(s) can include only one request to a corresponding server or parallel requests to multiple different servers using the same or different network protocols and connection types.

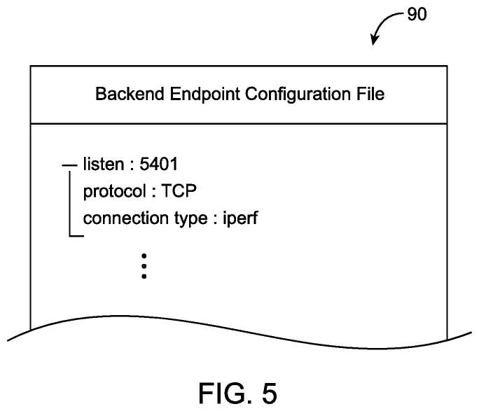

FIG. 5 is a diagram of an illustrative configuration file 90 for a backend endpoint in accordance with some embodiments. The backend endpoint can only receive requests from one or more clients. As shown in FIG. 5, backend endpoint configuration file 90 may direct the backend endpoint to listen for requests on designated port 5401 via a link established using TCP with the iperf connection type. The backend endpoint may then respond with the requisite information via the established TCP link. This example in which a backend endpoint is configured to listen for requests on a given port is merely illustrative. In general, a backend endpoint can be configured to listen for requests from any number of ports to service any number of clients.

The behavior of each client and service in a multi-tiered application to be emulated by a traffic generation tool in accordance with some embodiments can thus be encoded using configuration files of the type described in connection with FIGS. 3, 4, and 5. The client endpoint configuration files for specifying the traffic pattern of one or more clients, the applicant endpoint configuration files for specifying the traffic pattern of one or more application endpoints with both client and server functionality, and the backend endpoint configuration files for specifying the traffic pattern of one or more backend endpoints with server-only (data-only) functionality can be written, for example, using YAML (Yet Another Markup Language), JSON (JavaScript Object Notation), Python, XML (Extensible Markup Language), HTML (HyperText Markup Language), SGML (Standard Generalized Markup Language), or other types of markup or data serialization language.

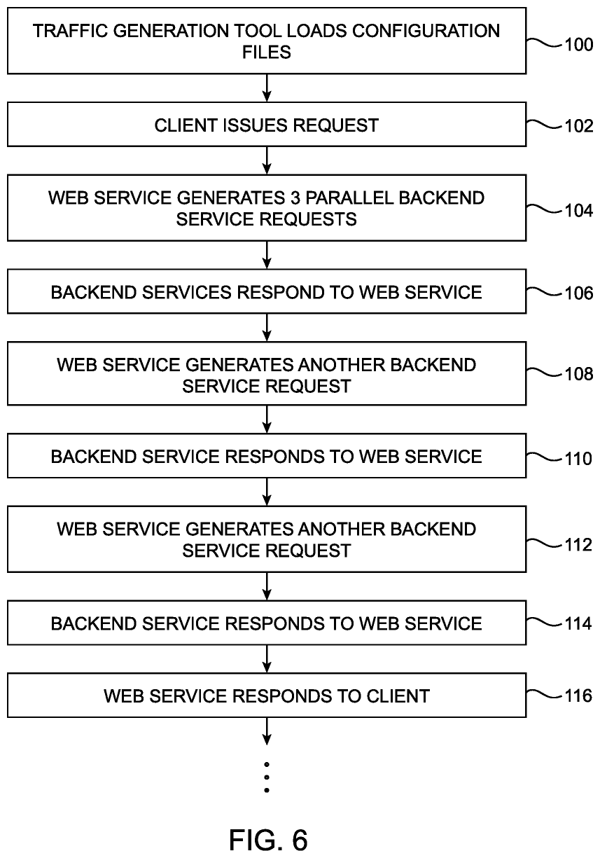

FIG. 6 is a flow chart of illustrative steps for operating a traffic generation tool to mimic a sequence of traffic flows in a multi-tiered application. During the operations of block 100, the traffic generation tool can load one or more configuration files of the types shown in connection with FIGS. 3, 4, and 5. Client configuration files can specify the behavior of client-only services or endpoints. Application configuration files can specify the behavior of services or endpoints in the application or other middleware tier with both client and server functionalities. Backend configuration files can specify the behavior of services or endpoints in the data tier. The subsequent blocks shown in the flow chart of FIG. 6 can be triggered by the traffic generation tool in accordance with the traffic pattern specified in the configuration files loaded during block 100.

During the operations of block 102, a client may issue a request to a corresponding application service such as a web service (see, e.g., web service 14 in FIG. 2 or web service 15 in FIG. 3). Traffic between the client and the web service may be conveyed using a first network protocol. During the operations of block 104, the web service can be configured to generate parallel (concurrent) requests to multiple backend services (e.g., to first, second, and third backend services). The three backend service requests can be sent at the same time and can establish links with three different backend servers using the same or different network communications protocols. Traffic between the web service and the first backend service may be conveyed using a second network protocol optionally different than the first network protocol. Traffic between the web service and the second backend service may be conveyed using a third network protocol optionally different than the first or second network protocol. Traffic between the web service and the third backend service may be conveyed using a fourth network protocol optionally different than the first, second, or third network protocol.

During the operations of block 106, one or more of the first, second, and third backend services may respond back to the web service. In response to receiving response(s) from the first, second, and/or third backend services, the web service an generate another request to a fourth backend service (see operation of block 108). Traffic between the web service and the fourth backend service may be conveyed using a fifth network protocol optionally different than the first, second, third, or fourth network protocol. The operations of block 108 can be triggered in response to receiving responses from all of the first, second, and third backend services. Alternatively, the operations of block 108 can be linked in response to receiving responses from any two of the first, second, and third backend services. Alternatively, the operations of block 108 can be automatically chained in response to receiving responses from any one of the first, second, and third backend services.

During the operations of block 110, the fourth backend service may respond back to the web service. In response to receiving the response from the fourth backend service, the traffic generation tool can direct the web service to generate yet another request to a fifth backend service (see operation of block 112). Traffic between the web service and the fifth backend service may be conveyed using a sixth network protocol optionally different than the first, second, third, fourth, or fifth network protocol. During the operations of block 114, the fifth backend service may respond back to the web service. In response to receiving the response from the fifth backend service, the traffic generation tool can direct the web service to send a response back to the original client.

The traffic sequencing example of FIG. 6 is merely illustrative and is not intended to limit the scope of the present embodiments. In general, the protocol-linking traffic generation tool can be configured to simulate any type of traffic between different tiers of a multi-tiered application. In general, one or more clients in a first tier can be configured to send requests to one or more frontend service(s) such as a web service in a second tier. Each service in the second tier can be configured to send concurrent backend requests to multiple corresponding services in a third tier and/or can be configured to schedule backend requests in series to different services in the third tier. If desired, one or more services in the third tier can be configured to send concurrent backend requests or to scheduled serial backend requests to different services in a fourth tier or beyond. If desired, two or more services in the third tier can asynchronously communicate with one another. If desired, two or more services in the fourth tier can asynchronously communicate with one another. If desired, a service in the third tier can asynchronously communicate with another service in the fourth tier.

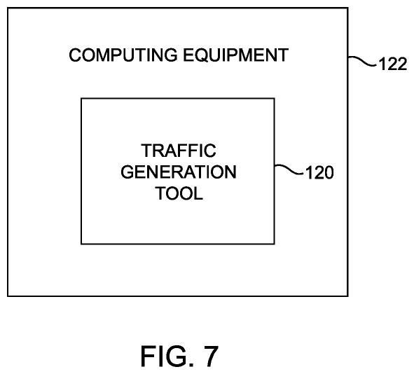

FIG. 7 is a diagram showing how the protocol-linking traffic generation tool such as traffic generation tool 120 can run on computing equipment 122. Computing equipment 122 may be based on any suitable computer or network of computers. Computing equipment 122 can include one or more computer(s) having sufficient processing and storage circuitry to run traffic generation tool 120 and to store corresponding simulation results. Computing equipment 122 can include a user interface for gathering user input and a display for displaying simulation results to a user. Software code for performing the operations of traffic generation tool 120 may be stored on non-transitory computer readable storage media (e.g., tangible computer readable storage media) stored on one or more of the components of computing equipment 122. The software code may sometimes be referred to as software, data, instructions, program instructions, or code. The non-transitory computer readable storage media may include drives, non-volatile memory such as non-volatile random-access memory (NVRAM), removable flash drives or other removable media, other types of random-access memory, etc. Software stored on the non-transitory computer readable storage media may be executed by the processing circuitry on computing equipment 122.

The foregoing is merely illustrative and various modifications can be made to the described embodiments. The foregoing embodiments may be implemented individually or in any combination.

What is claimed is:

1. A method of operating a traffic generation tool to simulate a multi-tiered application having at least one frontend service and a plurality of backend services, the method comprising:
loading configuration files specifying a behavior of each of the at least one frontend service and the plurality of backend services;
with a client, sending a client request to the at least one frontend service;
in response to receiving the client request, sequencing a chain of additional requests involving one or more different network protocols to the plurality of backend services.

2. The method of claim 1, wherein sequencing the chain of additional requests comprises sending a set of concurrent requests to two or more backend services in the plurality of backend services.

3. The method of claim 1, wherein sequencing the chain of additional requests comprises sending at least three requests in series to three or more backend services in the plurality of backend services.

4. The method of claim 1, wherein sequencing the chain of additional requests comprises:
triggering a set of concurrent requests to two or more backend services in the plurality of backend services; and
serially triggering at least two requests to two or more backend services in the plurality of backend services.

5. The method of claim 4, wherein triggering the set of concurrent requests comprises sending a first request to a first backend service in the plurality of backend services via a first link established using a first network protocol and simultaneously sending a second request to a second backend service in the plurality of backend services via a second link established using a second network protocol different than the first network protocol.

6. The method of claim 4, wherein serially triggering at least two requests comprises:
sending a first request to a first backend service in the plurality of backend services via a first link established using a first network protocol; and
subsequent to the first backend service responding to the first request, sending a second request to a second backend service in the plurality of backend services via a second link established using a second network protocol different than the first network protocol.

7. The method of claim 4, further comprising:
simulating traffic between two or more backend services in the plurality of backend services.

8. The method of claim 1, wherein the configuration files comprise a client configuration file that specifies an address and a port of a server to which the client can send the client request, a type of network protocol used to convey the client request to the server, and a response field that determines how the client behaves when receiving a corresponding response from the server.

9. The method of claim 1, wherein the configuration files comprise an application configuration file that specifies a port for monitoring the client request, a type of network protocol used for communicating with the client, first servers to which concurrent backend requests are sent, second servers to which serial backend requests are sent, and a response field that determines how the frontend service behaves when receiving corresponding responses from the first and second servers.

10. The method of claim 1, wherein the configuration files comprise a backend configuration file that specifies a port for monitoring a backend request from the frontend service and a type of network protocol used for communicating with the frontend service.

11. A method of emulating traffic in a multi-tiered application, the method comprising:
sending a request from a client in a first tier of the multi-tiered application to a service in a second tier of the multi-tiered application; and
in response to receiving the request at the service in the second tier, automatically triggering a chain of requests from the service in the second tier to a plurality of backend services in a third tier of the multi-tiered application.

12. The method of claim 11, wherein triggering the chain of requests comprises issuing parallel requests to two or more backend services in the plurality of backend services in the third tier.

13. The method of claim 11, wherein triggering the chain of requests comprises issuing requests in series to two or more backend services in the plurality of backend services in the third tier.

14. The method of claim 11, further comprising:
loading configuration files that specify a behavior of each endpoint in the client in the first tier, the service in the second tier, and the plurality of backend services in the third tier.

15. The method of claim 14, wherein the configuration files comprise a first type of configuration files for specifying client-only functionality for endpoints in the first tier, a second type of configuration files for specifying server-only functionality for endpoints in the third tier, and a third type of configuration files for specifying both client and server functionality for endpoints in the second tier.

16. The method of claim 11, further comprising:
in response to receiving a request at a given backend service in the plurality of backend services, automatically triggering an additional request from the given backend service in the third tier to another backend service in a fourth tier of the multi-tiered application.

17. A non-transitory computer-readable storage medium storing one or more programs configured to be executed by computing equipment running a traffic generation tool for mimicking traffic in a multi-tiered application, the one or more programs including instructions for:
sending a request from a client to a web server;
in response to receiving the request at the web server, directing the web server to initiate traffic with one or more first backend servers; and
in response to receiving one or more response from the one or more first backend servers, directing the web server to initiate traffic with one or more second backend servers.

18. The non-transitory computer-readable storage medium of claim 17, wherein the instructions for directing the web server to initiate traffic with one or more first backend servers comprise instructions for directing the web server to send concurrent requests to the first backend servers using two or more different network communications protocols.

19. The non-transitory computer-readable storage medium of claim 17, wherein the instructions for directing the web server to initiate traffic with one or more second backend servers comprise instructions for directing the web server to send concurrent requests to the second backend servers using two or more different network communications protocols.

20. The non-transitory computer-readable storage medium of claim 17, further comprising:
in response to receiving one or more response from the one or more second backend servers, directing the web server to initiate traffic with one or more third backend servers.
